(19) United States
(12) Patent Application Publication
(10) Pub. No.: US 2026/0122986 A1
(43) Pub. Date: Apr. 30, 2026

(54) SEMICONDUCTOR DEVICE AND METHOD OF MANUFACTURING THE SAME

(71) Applicant: Renesas Electronics Corporation, Tokyo (JP)

(72) Inventors: Satoshi EGUCHI, Tokyo (JP); Yasunori YAMASHITA, Tokyo (JP); Yanzhe WANG, Tokyo (JP); Kenichi HISADA, Tokyo (JP)

(21) Appl. No.: 19/303,434

(22) Filed: Aug. 19, 2025

(30) Foreign Application Priority Data
Oct. 24, 2024 (JP) 2024-187599

(51) Int. Cl. H10D 62/10; H10D 30/01; H10D 30/66; H10D 62/832; H10D 84/83

(52) U.S. Cl. CPC H10D 62/111; H10D 30/0291; H10D 30/665; H10D 84/839; H10D 62/8325

(57) ABSTRACT

Improve a breakdown voltage and reliability of a semiconductor device. A plurality of semiconductor elements is formed in a cell region. A termination region surrounds the cell region in plan view. In a semiconductor substrate of the termination region, a p-type RESURF region is formed to reach a predetermined depth from an upper surface of the semiconductor substrate. The RESURF region is annularly formed in the termination region to surround the cell region in plan view. The RESURF region contains boron as an impurity.

### CROSS-REFERENCE TO RELATED APPLICATIONS

The disclosure of Japanese Patent Application No. 2024-187599 filed on Oct. 24, 2024, including the specification, drawings and abstract is incorporated herein by reference in its entirety.

### BACKGROUND

The present invention relates to a semiconductor device and its manufacturing method, particularly to a semiconductor device using a semiconductor substrate made of silicon carbide and its manufacturing method.

Semiconductor devices equipped with semiconductor elements such as power MOSFETs (Metal Oxide Semiconductor Field Effect Transistors) are widely used. Silicon carbide (SiC) has an electric field strength for dielectric breakdown that is about an order of magnitude greater than that of silicon (Si). Therefore, in power MOSFETs using SiC substrates, a drift region that maintains the breakdown voltage can be thinned to about 1/10, and an impurity concentration can be increased by about 100 times, theoretically reducing the element resistance by more than three orders of magnitude. Additionally, the bandgap of SiC is about three times larger than that of Si, allowing power MOSFETs using SiC substrates to operate at high temperatures.

Such high breakdown voltage semiconductor devices include a cell region where a plurality of semiconductor elements is formed and a termination region that surrounds the cell region in plan view. A source voltage, such as 0V, is applied to the innermost periphery of the termination region, and a drain voltage, such as 1000V or more, is applied to the outermost periphery. Therefore, it is necessary to maintain the breakdown voltage of the semiconductor device in the termination region. For example, in Patent Document 1 (Japanese Unexamined Patent Application Publication No. 2018-98288), a RESURF region, which is a p-type impurity region, is formed in the semiconductor substrate of the termination region. The RESURF region is formed annularly to surround the cell region in plan view.

### SUMMARY

To improve the breakdown voltage of a semiconductor device in the termination region, it is preferable to smooth the shape of the corner portion of the RESURF region in cross-section and alleviate the electric field at the corner portion.

However, when forming a p-type impurity region in an SiC substrate, ion implantation using aluminum (Al) is typically performed. In the SiC substrate, aluminum is known to activate through heat treatment but does not diffuse. Therefore, the cross-sectional shape of the corner portion of the RESURF region remains almost the same as the cross-sectional shape during ion implantation, resulting in sharp corners. Consequently, the electric field tends to concentrate at the corner portion, making it difficult to improve the breakdown voltage and reliability of the semiconductor device, especially in high-temperature reverse bias tests.

To achieve a gentle shape for the corner portion of the p-type RESURF region, a method involving a plurality of masks with different opening widths and multiple ion implantations with different implantation energies can be considered. For example, with a mask having a small opening width, ion implantation is performed with a large implantation energy, and as the opening width increases, the implantation energy is reduced. This allows the corner portion of the RESURF region to be shaped in a stepped manner, approaching a gentle shape.

However, forming the RESURF region using such a method requires increasing a number of masks and the number of ion implantations. For instance, more than seven masks and more than seven ion implantations are necessary. In other words, the more gentle the shape of the corner portion is made to improve the breakdown voltage of the semiconductor device, the more the manufacturing cost increases.

Other problems and novel features will become apparent from the description of this specification and the accompanying drawings.

In one embodiment, a semiconductor device includes a cell region where a plurality of semiconductor elements is formed, a termination region that surrounds the cell region in plan view, a semiconductor substrate of a first conductivity type made of silicon carbide having an upper surface and a bottom surface, and a first impurity region of a second conductivity type opposite to the first conductivity type formed in the semiconductor substrate of the termination region to reach a predetermined depth from the upper surface. The first impurity region is formed annularly in the termination region to surround the cell region in plan view, contains boron as an impurity, and a virtual curve indicating a junction surface between the first impurity region and the semiconductor substrate has a predetermined radius of curvature.

A manufacturing method of a semiconductor device in one embodiment includes a cell region where a plurality of semiconductor elements is formed and a termination region that surrounds the cell region in plan view. The manufacturing method includes: (a) preparing an n-type semiconductor substrate made of silicon carbide having an upper surface and a bottom surface; (b) forming a p-type first impurity region in the semiconductor substrate of the termination region to reach a predetermined depth from the upper surface. The first impurity region is formed annularly in the termination region to surround the cell region in plan view and has a central portion, an inner end portion closer to the cell region than the central portion and an outer end portion farther from the cell region than the central portion. The (b) step includes: (b1) ion implanting boron using a first mask film in the locations of the central portion, the inner end portion and the outer end portion of the semiconductor substrate; (b2) ion implanting carbon using a second mask film in the locations of the inner end portion and the outer end portion of the semiconductor substrate; (b3) after the (b1) and (b2) steps, performing heat treatment to diffuse the boron contained in the central portion, the inner end portion and the outer end portion.

According to one embodiment, the breakdown voltage and reliability of the semiconductor device can be improved.

### BRIEF DESCRIPTION OF THE DRAWINGS

FIG. 1 is a plan view showing a semiconductor device in the first embodiment.

FIG. 2 is a plan view showing the semiconductor device in the first embodiment.

FIG. 3 is a cross-sectional view showing a cell region and a termination region in the first embodiment.

FIG. 4 is an enlarged cross-sectional view showing the surroundings of the MOSFET in the cell region and a RESURF region in the termination region in the first embodiment.

FIG. 5 is a cross-sectional view showing details of the RESURF region in the termination region in the first embodiment.

FIG. 6 is a cross-sectional view showing details of the RESURF region in the termination region in the first embodiment.

FIG. 7 is an impurity profile of the RESURF region in the first embodiment.

FIG. 8 is a cross-sectional view showing a manufacturing step of the semiconductor device in the first embodiment.

FIG. 9 is a cross-sectional view showing a manufacturing step of the semiconductor device following FIG. 8.

FIG. 10 is a cross-sectional view showing a manufacturing step of the semiconductor device following FIG. 9.

FIG. 11 is a cross-sectional view showing a manufacturing step of the semiconductor device following FIG. 10.

FIG. 12 is a cross-sectional view showing a manufacturing step of the semiconductor device following FIG. 11.

FIG. 13 is a cross-sectional view showing a manufacturing step of the semiconductor device following FIG. 12.

FIG. 14 is a cross-sectional view showing a manufacturing step of the semiconductor device following FIG. 13.

FIG. 15 is a cross-sectional view showing a manufacturing step of the semiconductor device following FIG. 14.

FIG. 16 is a cross-sectional view showing a manufacturing step of the semiconductor device following FIG. 15.

FIG. 17 is a cross-sectional view showing a manufacturing step of the semiconductor device following FIG. 16.

FIG. 18 is a cross-sectional view showing a semiconductor device in a modified example.

### DETAILED DESCRIPTION

Hereinafter, embodiments will be described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the present application, the X direction, Y direction, and Z direction intersect each other and are orthogonal to each other. In this application, the Z direction is the vertical direction, depth direction, or thickness direction of a certain structure. The expressions “plan view” or “in plan view” used in this application mean viewing the plane formed by the X direction and Y direction from the Z direction.

### Embodiment 1

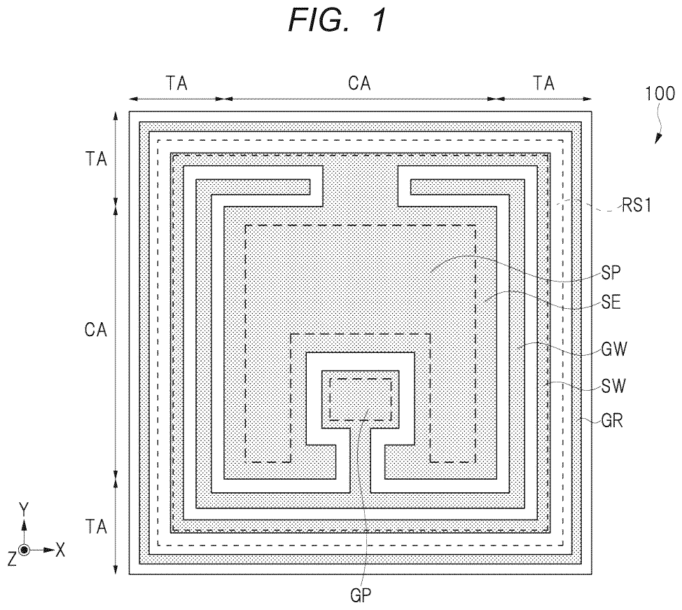

A semiconductor device 100 in the first embodiment will be described with reference to FIGS. 1 to 4.

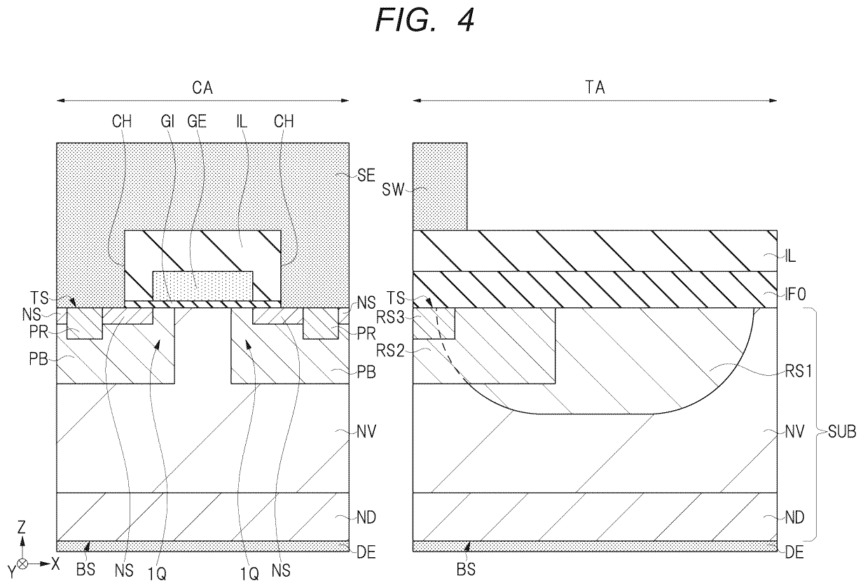

As shown in FIG. 1, the semiconductor device 100 includes a cell region CA where a plurality of semiconductor elements is formed, and a termination region TA surrounding the cell region CA in plan view. In the first embodiment, an example of the semiconductor element is an n-type MOSFET1Q as shown in FIG. 4. As shown in FIG. 1, the semiconductor device 100 includes a plurality of wirings. In the cell region CA, a source electrode SE is formed as wiring. The plurality of MOSFET1Q is formed below the source electrode SE. In the termination region TA, a gate wiring GW, a source wiring SW and guard ring wiring GR are formed as respective wirings.

The gate wiring GW surrounds the source electrode SE in plan view. The source wiring SW is drawn out from the source electrode SE and is formed annularly to surround the gate wiring GW in plan view. The guard ring wiring GR is formed annularly to surround the source wiring SW in plan view.

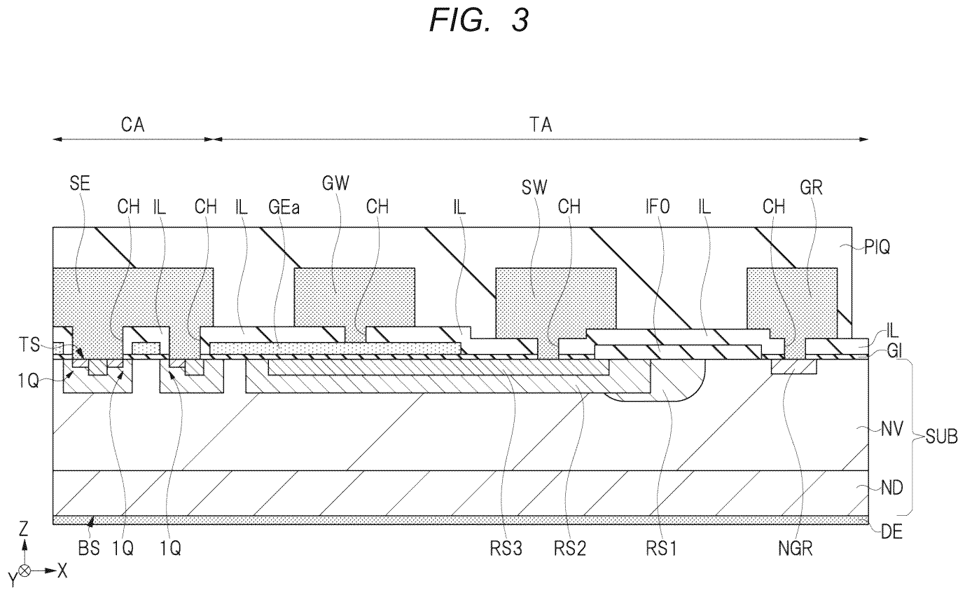

As shown in FIG. 3, the source electrode SE, the gate wiring GW, the source wiring SW and the guard ring wiring GR are covered with a protective film PIQ. An opening is provided in a part of the protective film PIQ. The protective film PIQ is a resin film, for example, a polyimide film.

As shown by the dashed lines in FIG. 1, a source pad SP and a gate pad GP are locations exposed at openings of the protective film PIQ on the source electrode SE and the gate wiring GW. By connecting external connection members to the source pad SP and the gate pad GP, the semiconductor device 100 can be electrically connected to other semiconductor devices, lead frames, or wiring substrates. The external connection members may be wires made of aluminum, gold, or copper, or clips made of copper plates.

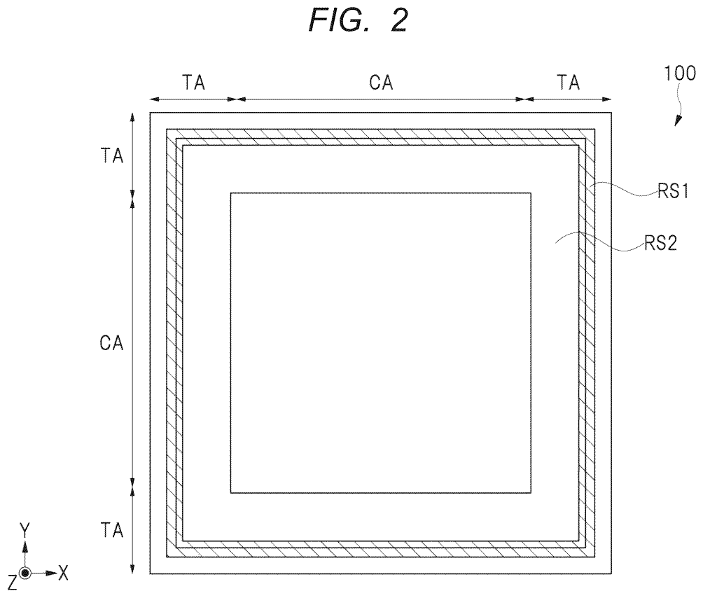

FIG. 2 shows a p-type RESURF region RS1 and a p-type RESURF region RS2 formed in a semiconductor substrate SUB of the termination region TA. The hatched area in FIG. 2 is the RESURF region RS1. A position of the RESURF region RS1 shown in FIG. 2 matches the position of the RESURF region RS1 shown by the dashed lines in FIG. 1.

The RESURF region RS1 and the RESURF region RS2 are each formed annularly in the termination region TA to surround the cell region CA in plan view. A part of the RESURF region RS1 and a part of the RESURF region RS2 are in contact with each other and overlap in plan view.

Below, the cross-sectional structure of the MOSFET1Q formed in the cell region CA and a cross-sectional structure of the termination region TA will be described with reference to FIGS. 3 and 4. The termination region TA in FIG. 4 is a part of FIG. 3 and shows an enlarged structure around the RESURF region RS1. In FIG. 4, an illustration of the protective film PIQ shown in FIG. 3 is omitted.

### Structure of MOSFET1Q in Cell Region Ca)

As shown in FIG. 4, the semiconductor substrate SUB has an upper surface TS and a bottom surface BS and is made of n-type silicon carbide (SiC). The semiconductor substrate SUB has an n-type drift region NV and an n-type drain region ND. The drain region ND is formed in the semiconductor substrate SUB to have a predetermined thickness from the bottom surface BS to the upper surface TS. An impurity concentration of the drain region ND is higher than that of the drift region NV.

The semiconductor substrate SUB may be a laminated body of an n-type SiC substrate and an n-type SiC layer formed on the n-type SiC substrate by an epitaxial growth method. In that case, the n-type silicon substrate constitutes the drain region ND, and the n-type SiC layer constitutes the drift region NV.

Below the bottom surface BS of the semiconductor substrate SUB, a drain electrode DE is formed. The drain electrode DE is a single-layer metal film such as an aluminum film, titanium film, nickel film, gold film, or silver film, or a laminated film obtained by laminating these metal films as appropriate. The drain region ND and the drain electrode DE are formed over the entire bottom surface BS of the semiconductor substrate SUB. The drain potential is supplied to the semiconductor substrate SUB (the drain region ND, the drift region NV) from the drain electrode DE.

On the upper surface TS of the semiconductor substrate SUB in the cell region CA, a gate electrode GE is formed via a gate dielectric film GI. The gate dielectric film GI is made of, for example, a silicon oxide film. The gate electrode GE is made of, for example, a polysilicon film in which n-type impurities are implanted.

In the semiconductor substrate SUB of the cell region CA, a p-type body region PB is formed to reach a predetermined depth from the upper surface TS of the semiconductor substrate SUB. In the body region PB, an n-type source region NS and a p-type high-concentration diffusion region PR are formed. An impurity concentration of the source region NS is higher than that of the drift region NV. An impurity concentration of the high-concentration diffusion region PR is higher than that of the body region PB.

The body region PB and the high-concentration diffusion region PR contain aluminum (Al) as an impurity. The source region NS contains nitrogen (N) as an impurity.

The gate electrode GE is formed to span a part of each of two adjacent body regions PB and the drift region NV located between the two adjacent body regions PB. A part of the body region PB located under the gate electrode GE via the gate dielectric film GI and between the source region NS and the drift region NV in plan view constitutes a channel region of the MOSFET1Q.

On the upper surface TS of the semiconductor substrate SUB, an interlayer insulating film IL is formed to cover the MOSFET1Q. The interlayer insulating film IL is, for example, a silicon oxide film. In the interlayer insulating film IL, holes CH are formed to reach the source region NS and the high-concentration diffusion region PR.

On the interlayer insulating film IL of the cell region CA, the source electrode SE is formed. The source electrode SE is also formed inside the holes CH and is electrically connected to the source region NS, the high-concentration diffusion region PR, and the body region PB, supplying a source potential to these impurity regions.

As shown in FIG. 3, a lead-out portion GEa is formed in the termination region TA. The lead-out portion GEa is integrated with the plurality of gate electrodes GE formed in the cell region CA. In the termination region TA, the holes CH are formed in the interlayer insulating film IL to reach the lead-out portion GEa. On the interlayer insulating film IL and inside the holes CH, the gate wiring GW is formed. The gate wiring GW is electrically connected to the lead-out portion GEa and supplies a gate potential to the gate electrode GE. Also, in the termination region TA, the holes CH reaching the semiconductor substrate SUB are formed in the interlayer insulating film IL.

### Structure of Termination Region TA

As shown in FIG. 3, a field dielectric film IF0 is formed on the upper surface TS of the semiconductor substrate SUB in the termination region TA. The field dielectric film IF0 is, for example, a silicon oxide film and has a greater thickness than the gate dielectric film GI. On the upper surface TS of the semiconductor substrate SUB, the interlayer insulating film IL is formed to cover the field dielectric film IF0. On the interlayer insulating film IL of the termination region TA, the gate wiring GW, the source wiring SW and the guard ring wiring GR are formed.

The source electrode SE, the gate wiring GW, the source wiring SW and the guard ring wiring GR are formed of, for example, a barrier metal film and a conductive film formed on the barrier metal film. The barrier metal film is, for example, a titanium tungsten film. The conductive film is, for example, an aluminum alloy film to which copper or silicon is added.

As shown in FIGS. 3 and 4, in the semiconductor substrate SUB of the termination region TA, the p-type RESURF region RS1, the p-type RESURF region RS2, and a n-type impurity region NGR are formed to reach a predetermined depth from the upper surface TS of the semiconductor substrate SUB. An impurity concentration of the impurity region NGR is higher than that of the drift region NV. A depth of the RESURF region RS1 is, for example, 0.5 micrometers or more and 1.5 micrometers or less. A depth of the RESURF region RS2 is shallower than that of the RESURF region RS1.

In the RESURF region RS2, a p-type RESURF region RS3 is formed. An impurity concentration of the RESURF region RS2 is higher than that of the RESURF region RS1. An impurity concentration of the RESURF region RS3 is higher than that of the RESURF region RS2.

The RESURF region RS2 and the RESURF region RS3 contain aluminum (Al) as an impurity. The RESURF region RS1 contains boron (B) and carbon (C) as impurities.

As shown in FIG. 3, the hole CH reaching the RESURF region RS3 is formed in the interlayer insulating film IL of the termination region TA, and the source wiring SW is also formed inside this hole CH. The source wiring SW is electrically connected to the RESURF regions RS3, RS2 and RS1, supplying a source potential to these impurity regions.

Additionally, the hole CH reaching the impurity region NGR is formed in the interlayer insulating film IL of the termination region TA and the guard ring wiring GR is also formed inside this hole CH. The guard ring wiring GR and the impurity region NGR are electrically connected to the drain electrode DE via the drift region NV and the drain region ND. Therefore, the drain electrode DE supplies a drain potential to the guard ring wiring GR and the impurity region NGR.

Although not shown, a silicide film may be formed on an upper surface of each of the impurity region NGR, the RESURF region RS3, the source region NS, the high-concentration diffusion region PR, and the lead-out portion GEa located at the bottom of the hole CH. Such silicide films are, for example, nickel silicide or titanium silicide.

### Detailed Configuration of the RESURF Region RS1

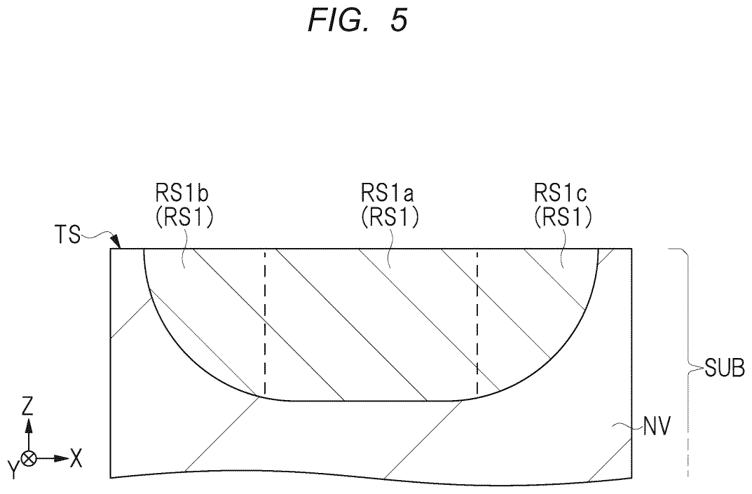

As shown in FIG. 5, the RESURF region RS1 has a central portion RS1a, an inner end portion RS1b closer to the cell region CA than the central portion RS1a, and an outer end portion RS1c farther from the cell region CA than the central portion RS1a. The central portion RS1a contains boron as an impurity. The inner end portion RS1b and the outer end portion RS1c contain boron and carbon as impurities.

As shown in the manufacturing method described later, boron is ion-implanted into the central portion RS1a, the inner end portion RS1b and the outer end portion RS1c, and carbon is ion-implanted into the inner end portion RS1b and the outer end portion RS1c, followed by heat treatment to diffuse the boron. During this process, the diffusion of boron in the inner end portion RS1b and the outer end portion RS1c are suppressed by carbon. As a result, the corner portion of the RESURF region RS1 becomes a gentle shape with curvature.

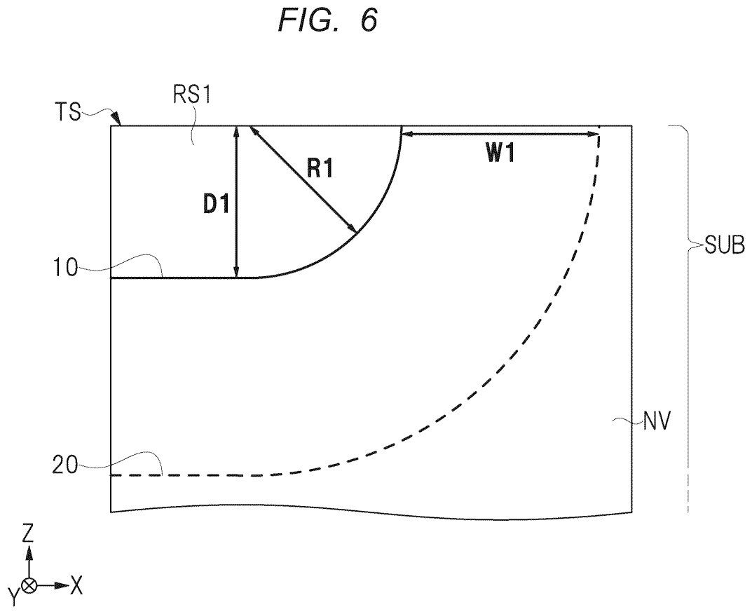

A virtual curve 10 shown in FIG. 6 indicates a junction surface between the RESURF region RS1 and the semiconductor substrate SUB (the drift region NV). A virtual curve 20 shown in FIG. 6 indicates a depletion layer extending from the RESURF region RS1. At the corner portion of the RESURF region RS1, the virtual curve 10 has a predetermined radius of curvature R1. The radius of curvature R1 is, for example, 0.5 micrometers or more and 1.5 micrometers or less.

By increasing the radius of curvature R1, it becomes easier to alleviate the electric field concentration at the corner portion of the RESURF region RS1, thereby improving the breakdown voltage of the semiconductor device 100. When the radius of curvature R1 is within the above numerical range, for example, even if 0V is applied to the source wiring SW and 700V to 4000V is applied to the drain electrode DE, the breakdown voltage of the semiconductor device 100 can be ensured.

However, it is preferable that the radius of curvature R1 is equal to or greater than the depth D1 of the RESURF region RS1 and should be less than or equal to a width W1 of the depletion layer extending from the RESURF region RS1. That is, it is preferable that the relationship “D1≤R1≤W1” is satisfied.

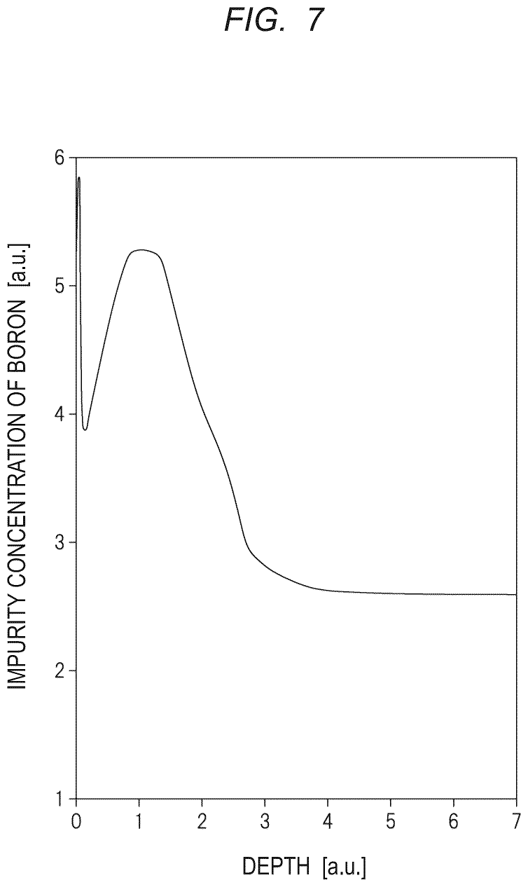

FIG. 7 shows an impurity concentration profile of the RESURF region RS1. As shown in FIG. 7, since boron is diffused by heat treatment, the impurity concentration profile of the RESURF region RS1 becomes a smooth curve.

### Manufacturing Method of Semiconductor Device

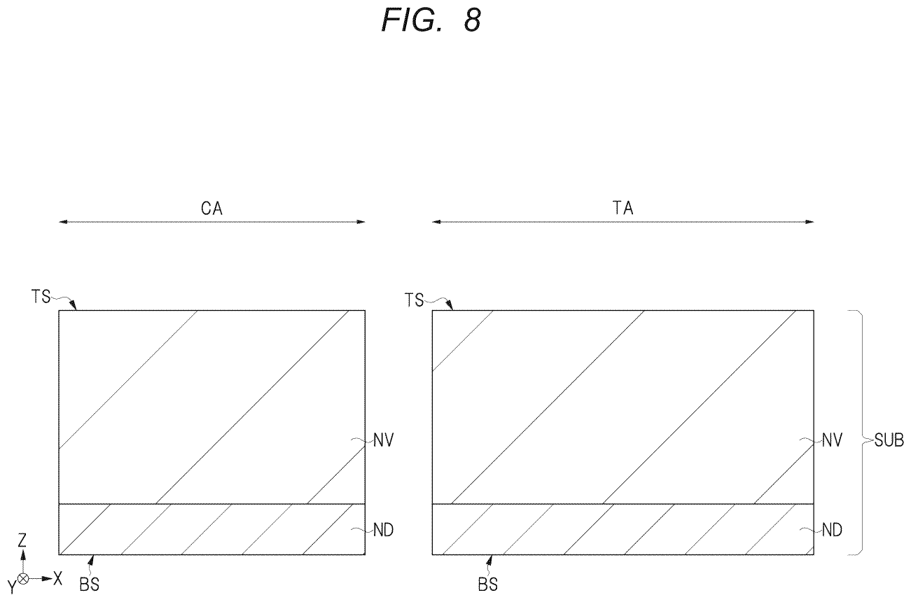

The manufacturing processes included in the manufacturing method of the semiconductor device 100 in the first embodiment will be described below with reference to FIGS. 8 to 17.

As shown in FIG. 8, an n-type semiconductor substrate SUB made of silicon carbide, having the upper surface TS and the bottom surface BS, is prepared. As described above, the semiconductor substrate SUB may be a laminated body of an n-type SiC substrate and an n-type SiC layer formed on the n-type SiC substrate by an epitaxial growth method. In this case, the n-type silicon substrate constitutes the drain region ND, and the n-type SiC layer constitutes the drift region NV.

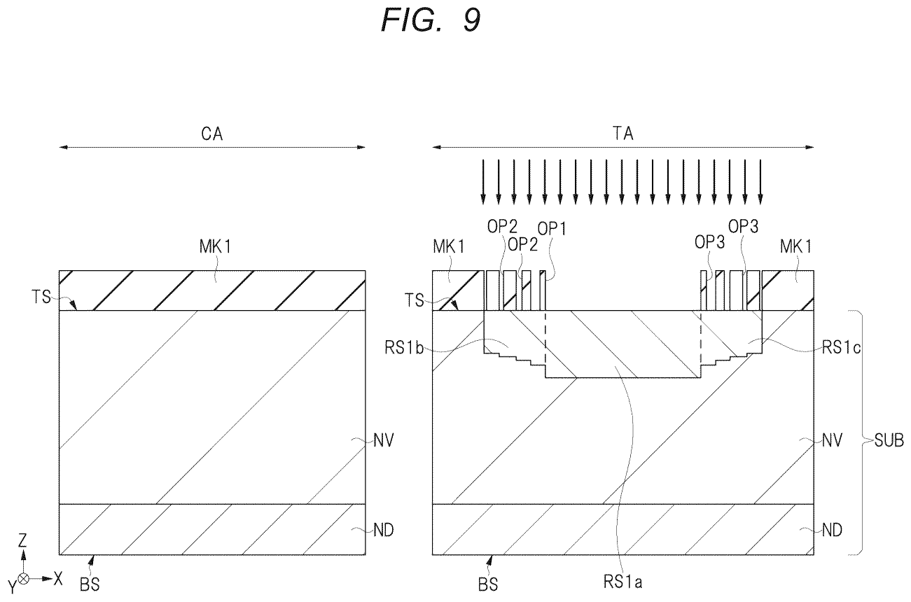

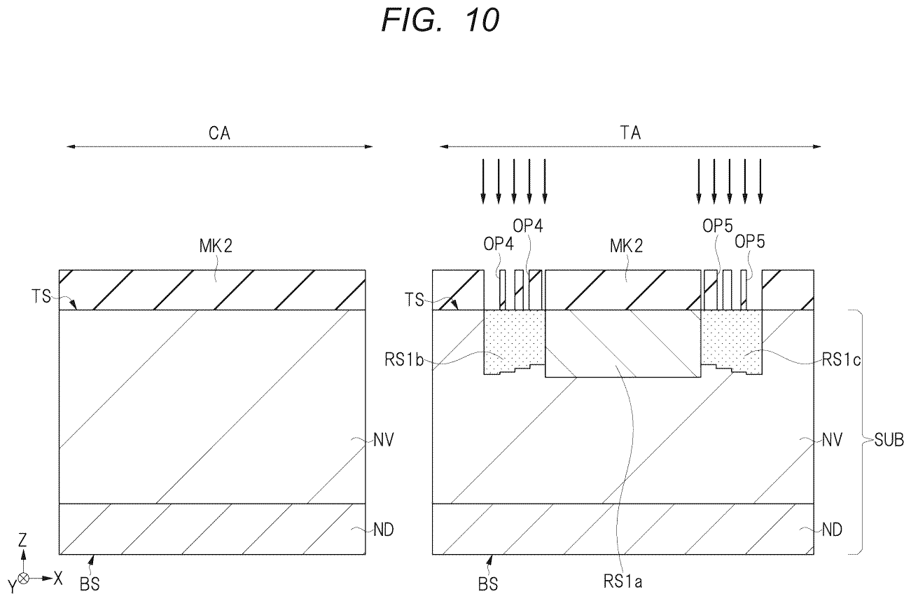

As shown in FIGS. 9 and 10, the p-type RESURF region RS1 having the central portion RS1a, the inner end portion RS1b, and the outer end portion RS1c is formed in the semiconductor substrate SUB of the termination region TA.

First, as shown in FIG. 9, a mask film MK1 is formed on the upper surface TS of the semiconductor substrate SUB, covering the cell region CA and an opening a part of the termination region TA. The mask film MK1 is, for example, a photoresist film. Next, boron (B) is ion-implanted into the locations in the semiconductor substrate SUB that will become the central portion RS1a, the inner end portion RS1b and the outer end portion RS1c using the mask film MK1. Then, the mask film MK1 is removed by, for example, an ashing process.

This ion implantation is performed under conditions where the implantation energy is 50 keV or more and 150 keV or less, and the dose amount is 1.0×10\hat{ }13 cm\hat{ }−2 or more and 3.0×10\hat{ }13 cm\hat{ }−2 or less. Additionally, within the range of the above conditions, the implantation energy and dose amount may be changed, and ion implantation may be performed in two separate steps.

As shown in FIG. 9, the mask film MK1 includes an opening pattern OP1 that opens the location that will become the central portion RS1a, a plurality of opening patterns OP2 that partially open the location that will become the inner end portion RS1b, and a plurality of opening patterns OP3 that partially open the location that will become the outer end portion RS1c. An opening width of each of the plurality of opening patterns OP2 and OP3 is narrower than an opening width of the opening pattern OP1. Additionally, the planar shape of each of the plurality of opening patterns OP2 and OP3 is dot-shaped or slit-shaped.

When the opening width is narrowed, ions tend to reach deeper positions less easily during ion implantation, and the amount of ion implantation decreases. Therefore, boron injected from the plurality of opening patterns OP2 and OP3 reaches shallower positions than boron injected from the opening pattern OP1. As a result, a depth of each of the inner end portion RS1b and the outer end portion RS1c becomes shallower than a depth of the central portion RS1a. Therefore, when boron is diffused by the heat treatment described later, it becomes easier to form the virtual curve 10 having the radius of curvature R1 as shown in FIG. 6.

The opening width of each of the plurality of opening patterns OP2 and OP3 becomes narrower as it moves away from the central portion RS1a. Therefore, in the inner end portion RS1b and the outer end portion RS1c, the position reached by boron becomes shallower as it moves away from the central portion RS1a, and the concentration of boron becomes lower. Therefore, it becomes easier to further form the virtual curve 10 as shown in FIG. 6.

Next, as shown in FIG. 10, a mask film MK2 is formed on the upper surface TS of the semiconductor substrate SUB, covering the cell region CA and opening the inner end portion RS1b and the outer end portion RS1c in the termination region TA. The mask film MK2 is, for example, a photoresist film. Next, carbon (C) is ion-implanted into the locations in the semiconductor substrate SUB that will become the inner end portion RS1b and the outer end portion RS1c using the mask film MK2. Then, the mask film MK2 is removed by, for example, an ashing process.

This ion implantation is performed under conditions where the implantation energy is 50 keV or more and 150 keV or less, and the dose amount is 1.0×10\hat{ }13 cm\hat{ }−2 or more and 3.0×10\hat{ }13 cm\hat{ }−2 or less. Additionally, within the range of the above conditions, the implantation energy and dose amount may be changed, and ion implantation may be performed in two separate steps.

As shown in FIG. 10, the mask film MK2 includes a plurality of opening patterns OP4 that partially open the location that will become the inner end portion RS1b, and a plurality of opening patterns OP5 that partially open the location that will become the outer end portion RS1c. An opening width of each of the plurality of opening patterns OP4 and OP5 is narrower than the opening width of the opening pattern OP1 of the mask film MK1. Additionally, the planar shape of each of the plurality of opening patterns OP4 and OP5 is dot-shaped or slit-shaped.

The opening width of each of the plurality of opening patterns OP4 and OP5 becomes wider as it moves away from the central portion RS1a. Therefore, in the inner end portion RS1b and the outer end portion RS1c, the position reached by carbon becomes deeper as it moves away from the central portion RS1a, and the concentration of carbon becomes higher. That is, as it moves away from the central portion RS1a, the diffusion of boron is more easily suppressed, making it easier to further form the virtual curve 10 as shown in FIG. 6.

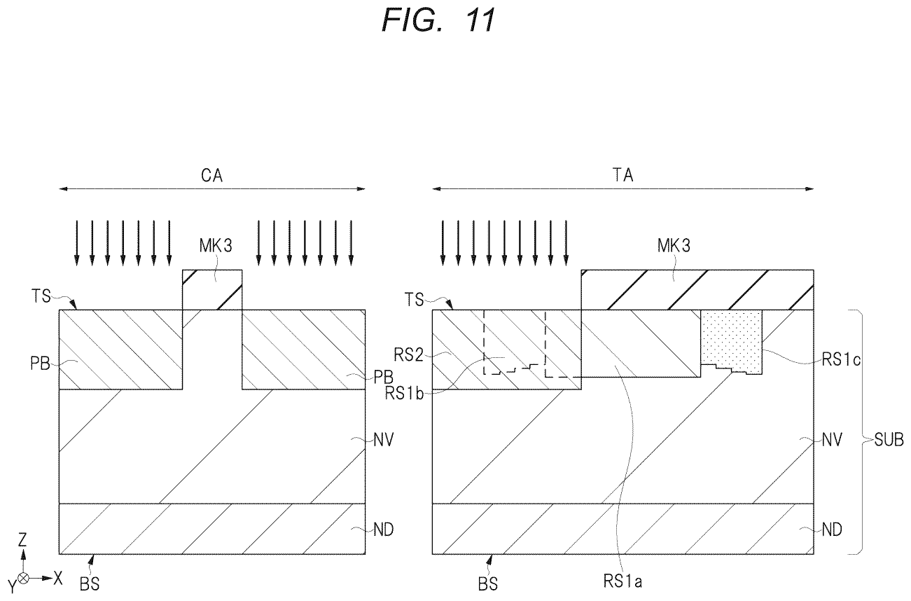

As shown in FIG. 11, a mask film MK3 is formed on the upper surface TS of the semiconductor substrate SUB, opening a part of the cell region CA and a part of the termination region TA. The mask film MK3 is, for example, a photoresist film. Next, by ion-implanting aluminum (Al) using the mask film MK3, the p-type body region PB is formed in the semiconductor substrate SUB of the cell region CA to reach a predetermined depth from the upper surface TS, and the p-type RESURF region RS2 is formed in the semiconductor substrate SUB of the termination region TA. The RESURF region RS2 is formed to be in contact with a part of the RESURF region RS1. Then, the mask film MK3 is removed by, for example, an ashing process.

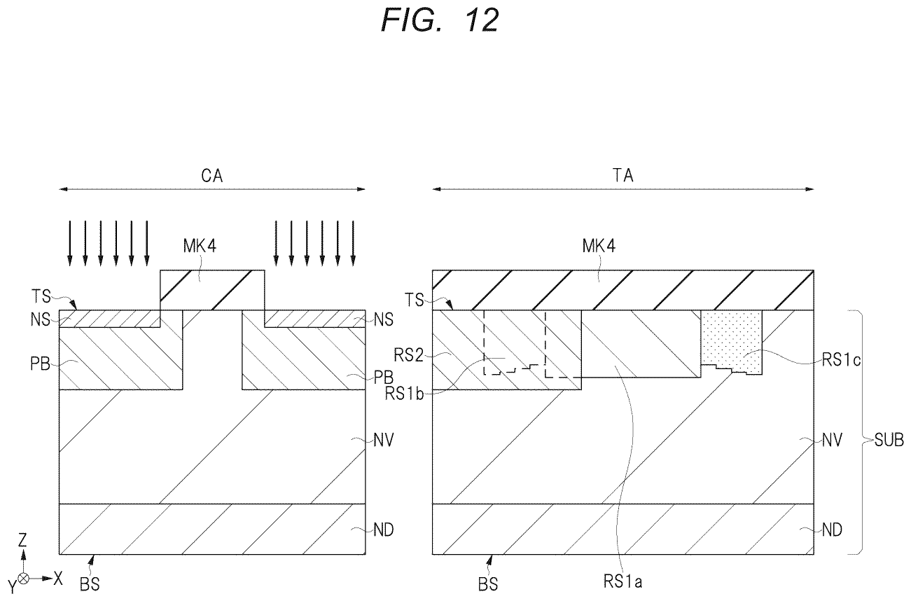

As shown in FIG. 12, a mask film MK4 is formed on the upper surface TS of the semiconductor substrate SUB, covering the termination region TA and an opening a part of the body region PB in the cell region CA. The mask film MK4 is, for example, a photoresist film. Next, using the mask film MK4, nitrogen (N) is ion-implanted to form the n-type source region NS in the body region PB. Then, for example, the mask film MK4 is removed by an ashing process.

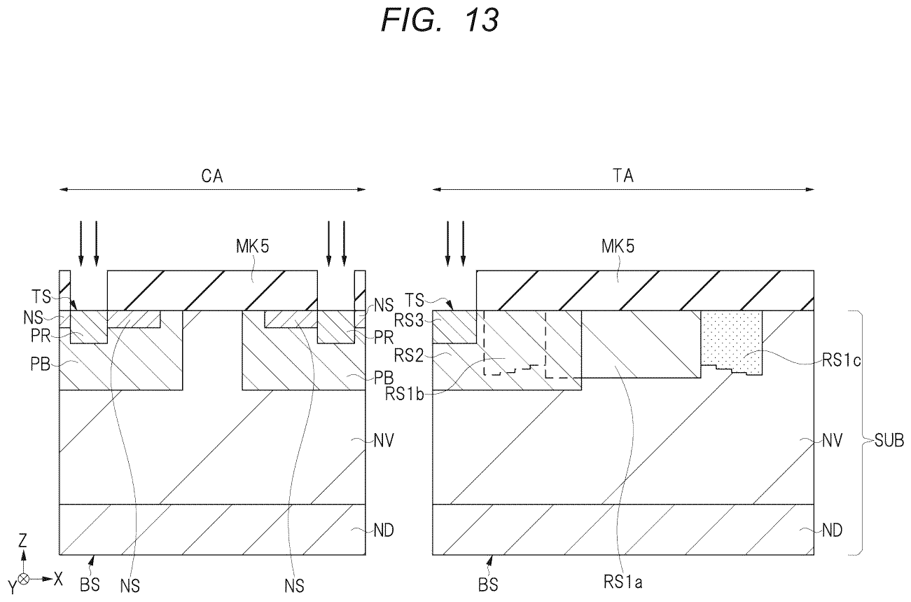

As shown in FIG. 13, a mask film MK5 is formed on the upper surface TS of the semiconductor substrate SUB, the opening the part of the body region PB in the cell region CA and a part of the RESURF region RS2 in the termination region TA. The mask film MK5 is, for example, a photoresist film. Next, using the mask film MK5, aluminum (Al) is ion-implanted to form the p-type high concentration diffusion region PR in the body region PB and the p-type RESURF region RS3 in the RESURF region RS2. Then, for example, the mask film MK5 is removed by an ashing process.

Subsequently, although not shown, a mask film is formed on the upper surface TS of the semiconductor substrate SUB, covering the cell region CA and an opening a part of the drift region NV in the termination region TA. The mask film is, for example, a photoresist film. Next, using the mask film, nitrogen (N) is ion-implanted to form the n-type impurity region NGR in the drift region NV (see FIG. 3). Then, for example, the mask film is removed by an ashing process.

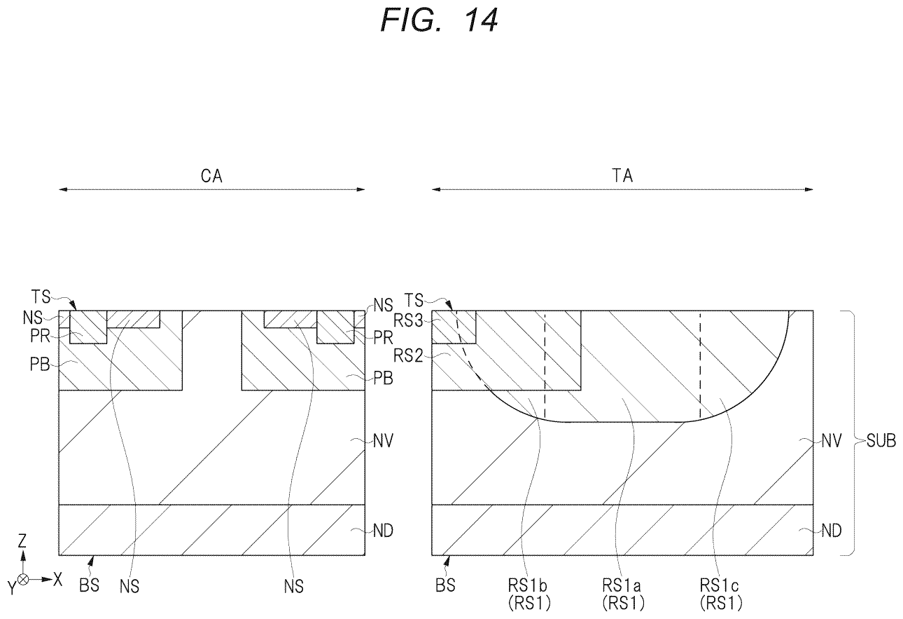

As shown in FIG. 14, heat treatment is performed to diffuse boron contained in the central portion RS1a, the inner end RS1b, and the outer end RS1c. This heat treatment also activates impurities (Al) contained in the body region PB, the high concentration diffusion region PR, the RESURF region RS2, and the RESURF region RS3, impurities (N) contained in the source region NS, and impurities (B) contained in the central portion RS1a, inner end RS1b, and outer end RS1c. This heat treatment is performed in an inert gas atmosphere under conditions of, for example, 1600 degrees Celsius or higher and 1800 degrees Celsius or higher.

Carbon is ion-implanted in the inner end RS1b and the outer end RS1c, but not in the central portion RS1a. Therefore, boron diffuses easily in the central portion RS1a, but its diffusion is suppressed by carbon in the inner end RS1b and the outer end RS1c. That is, in the heat treatment, the diffusion of boron in the inner end RS1b and the outer end RS1c is smaller than that in the central portion RS1a. As a result, the corner portion of the RESURF region RS1 becomes a gentle shape with curvature.

On the other hand, aluminum and nitrogen do not diffuse during the heat treatment. Therefore, the cross-sectional shapes of the body region PB, the high concentration diffusion region PR, the RESURF region RS2, the RESURF region RS3 and the source region NS are almost the same as their cross-sectional shapes during ion implantation.

In the first embodiment, such the RESURF region RS1 can be formed by ion-implanting boron and carbon using two masks (the mask film MK1, the mask film MK2), which can suppress the increase in manufacturing costs compared to the method described in the challenges of this application.

Note that the manufacturing steps of FIGS. 9 and 10 may be performed before the heat treatment of FIG. 14, and may also be performed after the manufacturing steps of FIGS. 11, 12, and 13.

Although photoresist films are exemplified as the mask films MK1, MK2, MK3, MK4 and MK5, these mask films may be patterned insulating films. Such insulating films may include, for example, silicon oxide films, silicon nitride films, or silicon oxynitride films.

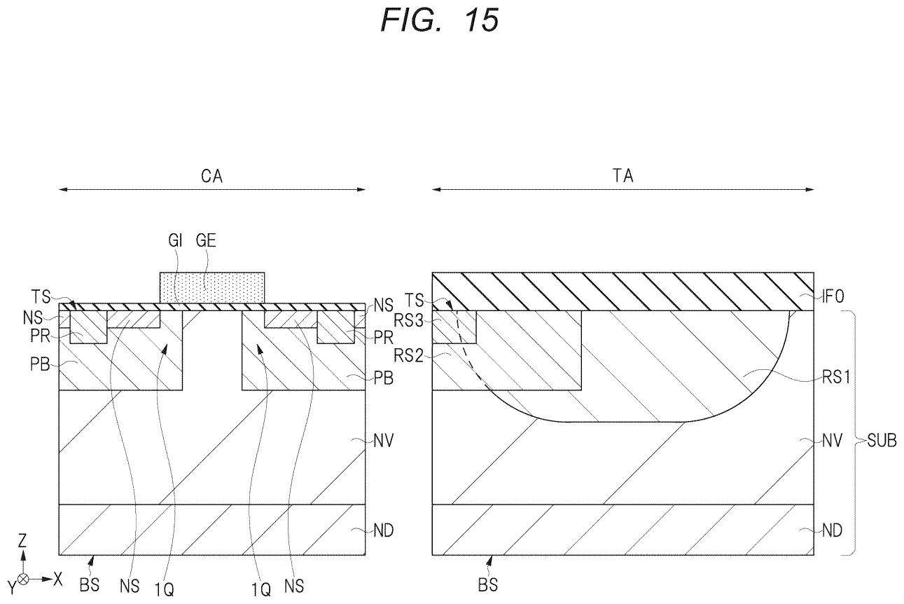

As shown in FIG. 15, a field insulating film IF0 is formed on the upper surface TS of the semiconductor substrate SUB by a film forming process using, for example, a CVD (Chemical Vapor Deposition) method. Next, by patterning the field insulating film IF0, the field insulating film IF0 located in the cell region CA is removed, leaving a part of the field insulating film IF0 in the termination region TA.

Next, the gate dielectric film GI is formed on the upper surface TS of the semiconductor substrate SUB by, for example, a thermal oxidation process. Then, a conductive film is formed on the gate dielectric film GI by a film forming process using, for example, a CVD method. The conductive film is, for example, a polysilicon film in which n-type impurities are introduced.

Next, by patterning the conductive film, the conductive film located in the termination region TA is removed, and the plurality of gate electrodes GE is formed on the gate dielectric film GI located in the cell region CA. The gate electrode GE is formed to span a part of each of the adjacent two body regions PB and the drift region NV located between the adjacent two body regions PB. In this way, a plurality of MOSFETs 1Q are formed in the cell region CA.

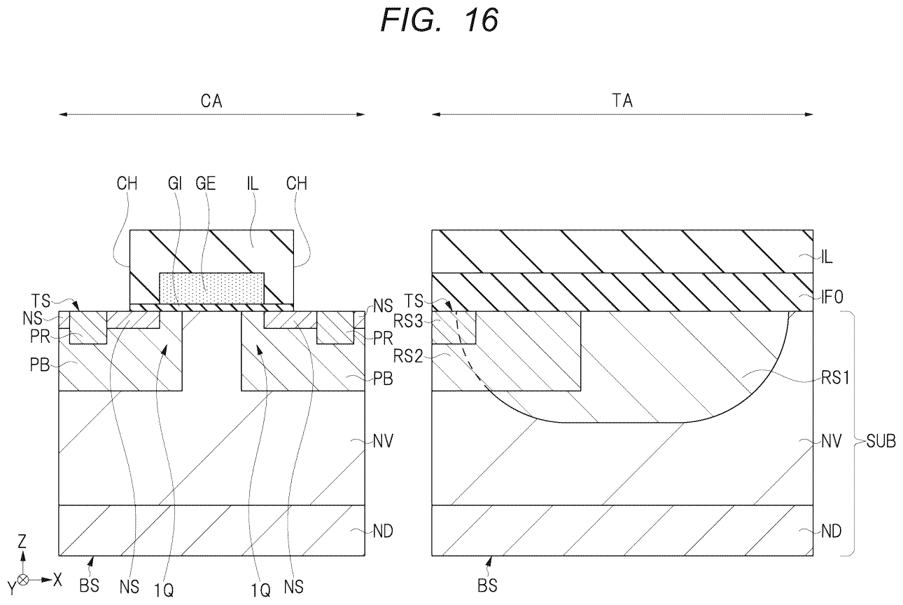

As shown in FIG. 16, an interlayer insulating film IL is formed on the upper surface TS of the semiconductor substrate SUB by a film forming process using, for example, a CVD method, covering the field insulating film IF0 in the termination region TA and the plurality of MOSFETs 1Q in the cell region CA.

Next, using photolithography and etching processes, the holes CH are formed in the interlayer insulating film IL. In the cell region CA, the holes CH are formed to reach the plurality of source regions NS and the plurality of high concentration diffusion regions PR. In the termination region TA, the holes CH are formed to reach the lead-out portion GEa, the RESURF region RS3, or the semiconductor substrate SUB (see FIG. 3).

Subsequently, although not shown, a silicide film may be formed by a salicide technique on the upper surface of the semiconductor substrate SUB, the RESURF region RS3, the source region NS, the high concentration diffusion region PR and the lead-out portion GEa located at the bottom of the holes CH.

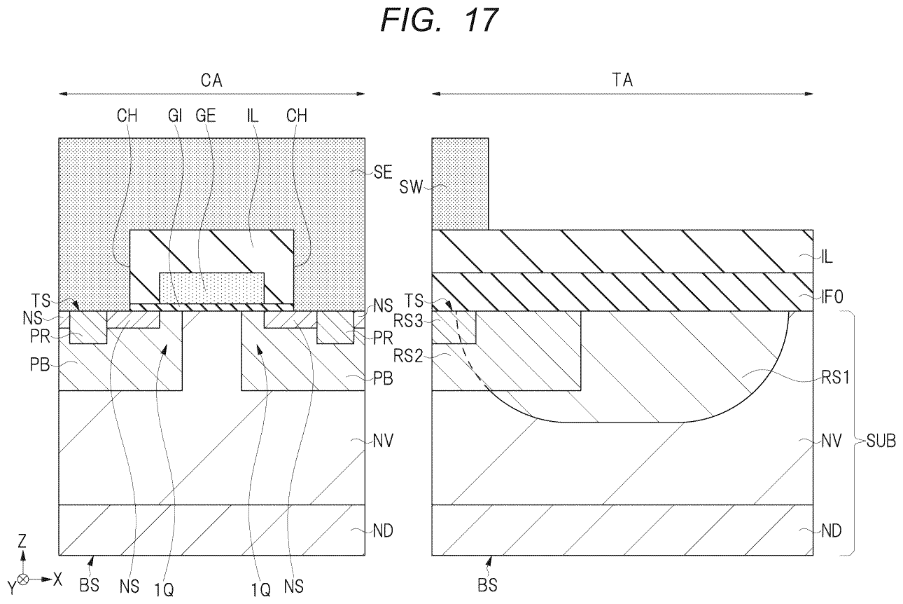

As shown in FIG. 17, a plurality of wirings including the source electrode SE and the source wiring SW are formed on the interlayer insulating film IL and inside the holes CH.

First, a barrier metal film is formed on the interlayer insulating film IL and inside the holes CH by a film forming process using, for example, a sputtering method. The barrier metal film is, for example, a titanium tungsten film. Next, a conductive film is formed on the barrier metal film by a film forming process using, for example, a sputtering method, so as to fill the insides of the holes CH. The conductive film is, for example, an aluminum alloy film to which copper or silicon is added.

Next, by patterning the barrier metal film and the conductive film, a plurality of wirings are formed. That is, the source electrode SE is formed as wiring in the cell region CA, and the gate wiring GW, the source wiring SW and guard ring wiring GR are formed as wirings in the termination region TA (see FIG. 3).

Subsequently, through the following manufacturing steps, the semiconductor device 100 shown in FIGS. 3 and 4 is manufactured. First, the protective film PIQ is formed to cover the source electrode SE, the gate wiring GW, the source wiring SW and guard ring wiring GR by a film forming process using, for example, a coating method. Next, an opening is formed in a part of the protective film PIQ to expose a part of each of the source electrode SE and the gate wiring GW. Then, the drain electrode DE is formed under a bottom surface BS of the semiconductor substrate SUB by a film forming process using, for example, a sputtering method.

### Modified Example

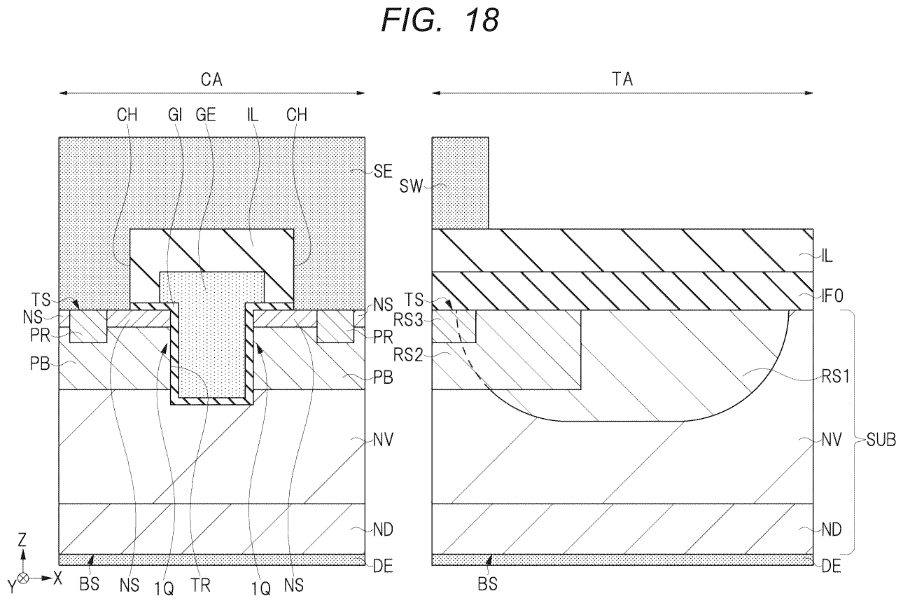

Below, using FIG. 18, a semiconductor device in the modified example of the first embodiment will be described. Note that the following description mainly explains the differences from the first embodiment, and the description of overlapping points with the first embodiment will be omitted.

In the first embodiment, a planar structure of the MOSFET 1Q is exemplified as the semiconductor element formed in the cell region CA, but the MOSFET 1Q may have a trench gate structure.

As shown in FIG. 18, a trench TR is formed in the semiconductor substrate SUB to reach a position deeper than the body region PB from the upper surface TS of the semiconductor substrate SUB. The manufacturing steps for forming the trench TR are performed before forming the gate dielectric film GI.

The gate dielectric film GI is formed on the upper surface TS of the semiconductor substrate SUB and inside the trench TR. The gate electrode GE is formed on the gate dielectric film GI to fill the inside of the trench TR. In the body region PB, the portion adjacent to the gate electrode GE via the gate dielectric film GI and located between the source NS and the drift region NV becomes the channel region of the MOSFET 1Q.

Note that among the plurality of trenches TR formed in the cell region CA, the depth of the RESURF region RS1 is preferably deeper than a depth of the trench TR to avoid a strong electric field being applied to the bottom of the trench TR closest to the termination region TA. The depth of the RESURF region RS1 is preferably deeper than the depth of the trench TR by, for example, 0.1 micrometers or more and 0.2 micrometers or less.

Although the present invention has been specifically described based on the embodiments, the present invention is not limited to these embodiments and can be variously modified without departing from the gist thereof.

For example, the semiconductor element formed in the cell region CA is not limited to a MOSFET and may be an IGBT or a Schottky barrier diode.

What is claimed is:

1. A semiconductor device comprising:
a cell region in which a plurality of semiconductor elements is formed;
a termination region surrounding the cell region in plan view;
a semiconductor substrate of a first conductivity type made of silicon carbide, having an upper surface and a bottom surface;
a first impurity region of a second conductivity type opposite to the first conductivity type formed in the semiconductor substrate of the termination region to reach a predetermined depth from the upper surface of the semiconductor substrate, wherein
the first impurity region is formed annularly in the termination region so as to surround the cell region in plan view,
the first impurity region contains boron as an impurity, and
a virtual curve indicating a junction surface between the first impurity region and the semiconductor substrate has a predetermined radius of curvature.

2. The semiconductor device according to claim 1, wherein
the radius of curvature is 0.5 micrometers or more and 1.5 micrometers or less.

3. The semiconductor device according to claim 1, wherein
the radius of curvature is greater than a depth of the first impurity region.

4. The semiconductor device according to claim 3, wherein
the radius of curvature is less than a width of a depletion layer extending from the first impurity region.

5. The semiconductor device according to claim 1, wherein
the first impurity region has a central portion, an inner end portion closer to the cell region than the central portion and an outer end portion farther from the cell region than the central portion,
the central portion contains boron as an impurity, and
the inner end portion and the outer end portion contain boron and carbon as impurities.

6. The semiconductor device according to claim 1, further comprising:
a second impurity region of the second conductivity type formed in the semiconductor substrate of the termination region to reach a predetermined depth from the upper surface of the semiconductor substrate, wherein
a depth of the second impurity region is shallower than a depth of the first impurity region,
the second impurity region contains aluminum as an impurity,
an impurity concentration of the second impurity region is higher than an impurity concentration of the first impurity region,
the second impurity region is formed annularly in the termination region so as to surround the cell region in plan view, and
the first impurity region surrounds the second impurity region in plan view and contacts a part of the second impurity region.

7. The semiconductor device according to claim 6, further comprising:
an interlayer insulating film formed above the upper surface of the semiconductor substrate;
a source wiring formed on the interlayer insulating film of the termination region and electrically connected to the second impurity region; and
a drain electrode formed below the bottom surface of the semiconductor substrate, wherein
the first impurity region is electrically connected to the source wiring via the second impurity region.

8. The semiconductor device according to claim 1, wherein
the plurality of semiconductor elements is MOSFET, IGBT, or Schottky barrier diode.

9. A method of manufacturing a semiconductor device in which a plurality of semiconductor elements is formed and a termination region surrounding the cell region in plan view, comprising:
(a) preparing a semiconductor substrate of n-type made of silicon carbide, having an upper surface and a bottom surface;
(b) forming a p-type first impurity region in the semiconductor substrate of the termination region to reach a predetermined depth from the upper surface of the semiconductor substrate, wherein
the first impurity region is formed annularly in the termination region to surround the cell region in plan view,
the first impurity region has a central portion, an inner end portion closer to the cell region than the central portion and an outer end portion farther from the cell region than the central portion, and
the step (b) includes:
(b1) implanting boron using a first mask film into the locations of the semiconductor substrate that become the central portion, the inner end portion, and the outer end portion;
(b2) implanting carbon using a second mask film into the locations of the semiconductor substrate that become the inner end portion and the outer end portion; and
(b3) after the step (b1) and before the step (b2), diffusing boron contained in the central portion, the inner end portion and the outer end portion by performing heat treatment.

10. The method of manufacturing the semiconductor device according to claim 9, wherein
in the step (b3), a diffusion of boron in the inner end portion and the outer end portion is smaller than a diffusion of boron in the central portion.

11. The method of manufacturing the semiconductor device according to claim 9, wherein
a virtual curve indicating a junction surface between the first impurity region and the semiconductor substrate has a predetermined radius of curvature.

12. The method of manufacturing the semiconductor device according to claim 11, wherein
the radius of curvature is 0.5 micrometers or more and 1.5 micrometers or less.

13. The method of manufacturing the semiconductor device according to claim 11, wherein
the radius of curvature is greater than a depth of the first impurity region.

14. The method of manufacturing the semiconductor device according to claim 13, wherein
the radius of curvature is less than a width of a depletion layer extending from the first impurity region.

15. The method of manufacturing the semiconductor device according to claim 9, wherein
the first mask film includes:
a first opening pattern that opens a location becoming the central portion;
a plurality of second opening patterns that partially open the location becoming the inner end portion; and
a plurality of third opening patterns that partially open the location becoming the outer end portion, wherein
each of an opening width of the plurality of second opening patterns and the plurality of third opening patterns is narrower than an opening width of the first opening pattern.

16. The method of manufacturing the semiconductor device according to claim 15, wherein
each of the opening width of the plurality of second opening patterns and the plurality of third opening patterns becomes narrower as they move away from the central portion.

17. The method of manufacturing the semiconductor device according to claim 15, wherein
the second mask film includes:
a plurality of fourth opening patterns that partially open the location becoming the inner end portion; and
a plurality of fifth opening patterns that partially open the location becoming the outer end portion, wherein
each of an opening width of the plurality of fourth opening patterns and the plurality of fifth opening patterns is narrower than the opening width of the first opening pattern.

18. The method of manufacturing the semiconductor device according to claim 17, wherein
each of the opening width of the plurality of fourth opening patterns and the plurality of fifth opening patterns becomes wider as they move away from the central portion.

19. The method of manufacturing the semiconductor device according to claim 9, further comprising:
(c) forming a p-type second impurity region in the semiconductor substrate of the termination region to reach a predetermined depth from the upper surface of the semiconductor substrate, wherein
a depth of the second impurity region is shallower than a depth of the first impurity region,
the second impurity region contains aluminum as an impurity,
an impurity concentration of the second impurity region is higher than an impurity concentration of the first impurity region,
the second impurity region is formed annularly in the termination region to surround the cell region in plan view, and
the first impurity region surrounds the second impurity region in plan view and contacts a part of the second impurity region.

20. The method of manufacturing the semiconductor device according to claim 19, further comprising:
(d) forming an interlayer insulating film on the upper surface of the semiconductor substrate;
(e) forming a source wiring on the interlayer insulating film of the termination region, electrically connected to the second impurity region; and
(f) forming a drain electrode below the bottom surface of the semiconductor substrate, wherein
the first impurity region is electrically connected to the source wiring via the second impurity region.
